(19) United States
(12) Patent Application Publication
(10) Pub. No.: US 2014/0137940 A1
(43) Pub. Date: May 22, 2014

(54) SOLAR CELL MODULE AND METHOD OF MANUFACTURING SAME

(71) Applicants: Kazuyo Endo, Chiyoda-ku (JP); Katsuhiro Imada, Chiyoda-ku (JP); Jun Fujita, Chiyoda-ku (JP)

(72) Inventors: Kazuyo Endo, Chiyoda-ku (JP); Katsuhiro Imada, Chiyoda-ku (JP); Jun Fujita, Chiyoda-ku (JP)

(73) Assignee: Mitsubishi Electric Corporation, Chiyoda-ku, Tokyo (JP)

(21) Appl. No.: 14/127,099

(22) PCT Filed: Jun. 18, 2012
(86) PCT No.: PCT/JP12/03949

§ 371 Date: Dec. 17, 2013

(30) Foreign Application Priority Data
Jun. 22, 2011 (JP) 2011-138555

(51) Int. Cl. H01L 31/048; H01L 31/18

(52) U.S. Cl. CPC H01L 31/0488; H01L 31/1864
USPC 136/259; 438/73

(57) ABSTRACT

A solar cell module is obtained by the following method. In a step of sealing a solar cell module using laminated glass, a solar cell and a translucent intermediate film layer which seals the solar cell are interposed between a front side glass substrate and a rear side glass substrate. A sealing member in which an insertion part and an exterior part are formed by folding a sealing sheet having a bonding surface on one side, is employed in the module peripheral edge. The insertion part is inserted between the front side glass substrate and the rear side glass substrate, and bonding surfaces thereof are bonded to the front side glass substrate and the rear side glass substrate. A bonding surface of the exterior part is bonded to an end face of at least either of the front side glass substrate and the rear side glass substrate.

### TECHNICAL FIELD

The invention relates to a sealing structure of a solar cell module using laminated glass and a manufacturing method thereof.

### DESCRIPTION OF THE RELATED ART

A solar cell module using a solar cell made from thin amorphous silicon or polycrystalline silicon, etc. is configured in such a way that a solar cell is disposed on a translucent insulating substrate such as a glass substrate, etc., and sealed by a resin. Normally, the glass substrate, which is to be a sunlight incident side, corresponds to a front side substrate of a solar cell. A method of sealing a solar cell is used, in which a solar cell is entirely covered with a sealing resin forming an intermediate film layer, and a back sheet is laminated on the sealing resin. As the sealing resin, for example, an ethylene-vinylacetate copolymer (EVA) is used, and as the back sheet, for example, a polyvinyl fluoride resin (PVF) is frequently used. In the sealing process for sealing, a vacuum laminating machine is often used, in which, while the sealing resin is heated, the inside of the module is decompressed and pressurized by a diaphragm. And a solar cell module shown in Patent Document 1 uses as a rear side substrate a glass substrate instead of a back sheet, constituting a so-called laminated glass solar cell module. Such a solar cell module has an advantage in that its vapor cut-off performance is superior to that of the module using a back sheet. Furthermore, since the solar cell module can have a certain strength by enhancing the mechanical strength of the rear face glass substrate, it can be employed as a building material for lighting windows making use of spaces between a plurality of solar cells arranged or the translucency of the solar cell itself. From the view point of applications, such a solar cell module is also called a building integrated solar cell module. In a laminated glass solar cell module, sealing members are disposed on the edges of glass substrates in such a manner as to enclose a solar cell and a sealing resin layer for its sealing. The sealing members are formed of materials containing polyisobutylene or a butyl rubber which have excellent insulating and waterproofing properties, and are inserted into peripheral edges between glass substrates so as to suppress the influence of moisture on the solar cell module (for example, refer to Patent Document 1). In a sealing process for a laminated glass solar cell module, a method using a vacuum laminating machine is also applicable.

### PRIOR ART DOCUMENT

### Patent Document

Patent Document 1: Japanese Laid-Open Patent Publication No. 2010-171400

### SUMMARY OF THE INVENTION

### Problems to be solved by the Invention

As described above, in a conventional laminated glass solar cell module, sealing of a panel-shaped solar cell module is carried out in such a manner that sealing members are disposed in the peripheral edges between the front side and rear side glass substrates. In the sealing process of such a solar cell module, the sealing member such as a butyl rubber expands, softens, and is deformed when heated and pressurized in a vacuum laminating machine. In this situation, when the thickness of the sealing member is decreased, the stress within the glass substrates in a sealing region becomes excessive, so that breakage of the glass substrates might occur. Furthermore, concerning this breakage phenomenon, since it is likely that the larger the substrate size becomes, the more frequently the breakage occurs in principle, this becomes a serious problem for a large-area module. The invention is accomplished to solve the above problem, and an object is to realize a laminated glass solar cell module in which an excess stress in the peripheral edges of glass substrates can be avoided in the sealing process, and breakage of glass substrates can be prevented.

### Means for Solving the Problems

A solar cell module according to the invention has a laminated glass structure in which a solar cell and a translucent intermediate film layer which seals the solar cell are interposed between a first glass substrate in a light receiving surface side and a second glass substrate in a rear surface side, wherein the solar cell module comprises a sealing member in a peripheral edge of the first glass substrate in which an insertion part and an exterior part are formed by folding a sealing sheet having a bonding surface on one side, the insertion part is formed by folding back the sealing sheet, the exterior part is formed to be connected continuously to the insertion part, the insertion part is inserted between the first glass substrate and the second glass substrate, and bonding surfaces thereof are bonded to the first glass substrate and the second glass substrate, and a bonding surface of the exterior part is bonded to an end face of the first glass substrate or the second glass substrate.

### Effect of the Invention

In a laminated glass solar cell module according to the invention, sealing of a peripheral edge is carried out in a manner that a sealing sheet is folded and inserted into a space for a sealing region of a glass substrate edge. Because of this, the stress in a peripheral edge of a glass substrate will not become excessive in a sealing process, so that breakage of a glass substrate can be avoided.

### BRIEF DESCRIPTION OF THE DRAWINGS

FIG. 1 shows a cross section of a solar cell module according to Embodiment 1.

FIG. 2 is a perspective view showing a shape of a sealing member according to Embodiment 1.

FIG. 3 is a perspective view showing an arrangement of sealing members according to Embodiment 1.

FIG. 4 is a cross sectional view showing a sealing state of a solar cell module according to Embodiment 1.

FIG. 5 is a perspective view showing a shape of a sealing member according to Embodiment 2.

FIG. 6 is a perspective view showing an arrangement of sealing members according to Embodiment 2.

FIG. 7 shows an enlarged cross section of an edge of a solar cell module having a structure according to Embodiment 3.

FIG. 8 shows an enlarged cross section of an edge of a solar cell module according to Embodiment 4.

FIG. 9 is a plan view showing a configuration of a thin film type solar cell module.

### EMBODIMENT FOR CARRYING OUT THE INVENTION

### Embodiment 1

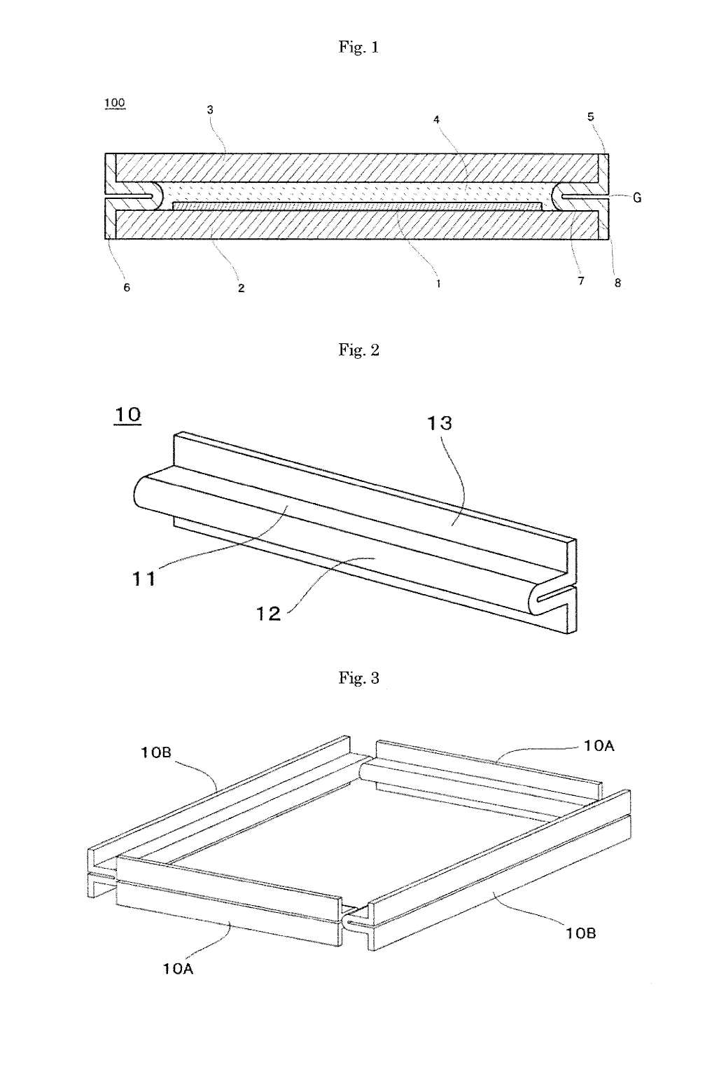

FIG. 1 is a cross sectional view of a laminated glass solar cell module 100 according to Embodiment 1 of the invention. A solar cell 1 is a unit element which generates photovoltaic power, and is disposed on a front side glass substrate 2 in a light receiving surface side. In addition, a solar cell 1 is entirely coated with a translucent intermediate film layer 4, and is sealed between the front side glass substrate 2 and a rear side glass substrate 3 through the intermediate film layer 4. In peripheral edges of both the glass substrates, a sealing member 5 and a sealing member 6 are disposed, so that the peripheral portion of the intermediate film layer 4 is insulated from the outside air. The sealing member 5 is a member which is formed by bending a piece of sealing sheet, and in which an insertion part and exterior parts are formed. The insertion part is a part which is inserted between the front side glass substrate 2 and the rear side glass substrate 3, and bonding surfaces thereof are bonded on the front side glass substrate 2 and the rear side glass substrate 3. The exterior part is a part which is along an end face of the front side glass substrate 2 or the rear side glass surface 3, and a bonding surface thereof is bonded on the end face of the front side glass substrate 2 or the rear side glass substrate 3. A horizontal bonding surface 7 of the sealing member 5 is a bonding surface in the insertion part facing in parallel with the front side glass substrate 2, and a vertical bonding surface 8 is a bonding surface in the exterior part facing the end face of the front side glass substrate 2. One side of the sealing sheet before formed as the sealing member 5 has a surface suitable for bonding, which is formed into the horizontal bonding surface 7 and the vertical bonding surface 8 in formation of the sealing member 5. For the intermediate film layer 4, a thermoplastic resin represented by an ethylene-vinylacetate copolymer (EVA) is used. The intermediate film layer 4 is softened by heating in a sealing process to function as a bonding material, and bonds both the substrates by filling up the space between the front side glass substrate 2 and the rear side glass substrate 3 while enclosing the solar cell 1 inside. Incidentally, in FIG. 1, there is only one solar cell 1 included in the solar cell module 100. However, in reality, a plurality of solar cells are arranged in a matrix shape to form a matrix.

FIG. 2 is a perspective view showing an example of a shape for the sealing member 5 and the sealing member 6, in which a sealing member 10 formed by folding a sealing sheet of 0.3 to 0.8 mm thickness having been cut out in strip form is shown. A horizontal bonding surface 11 is a surface which is to face a surface of the glass substrate, a folding back portion 12 is approximately a semi-cylindrical portion made by bending the sealing sheet, and a vertical bonding surface 13 is a surface which is to face an end face of the glass substrate. A pair of horizontal bonding surfaces 11 are provided in the upper and lower side, and a portion including the horizontal bonding surfaces 11 and the folding back part 12 constitutes an insertion part of the sealing member 10. A portion including the vertical bonding surface 13 constitutes an exterior part of the sealing member 10. In the same way, a pair of vertical bonding surfaces 13 are provided in the upper and lower side.

As a sealing sheet, a multilayer film including layers of a polyvinyl fluoride resin (PVF), a polyvinylidene fluoride (PVDF), or a polyethylene terephthalate resin (PET), is employed. Particularly, fluoride-based materials as described above have excellent moistureproofing and mechanical properties, and when employed as a sealing sheet, they become excellent sealing members. In addition, it is preferable that an EVA film is formed on the horizontal bonding surface 11 and the surface of the folding back part 12 in the sealing member 10 which are in contact with the intermediate film layer 4, the front side glass substrate 2, and the rear side glass substrate 3, in order to enhance an adherence property with the intermediate film layer 4. Concerning the bonding of the sealing member to the glass substrates, although a function of the intermediate film layer 4 melting and intruding into an interface can be expected, owing to the EVA film on the sealing sheet, secure bonding to the glass substrates and fusion bonding with the intermediate film layer 4 are obtained, realizing a solar cell module 100 with less voids. Namely, the sealing member 10 is formed in such a way that a sealing sheet, on which the EVA film is formed, is cut out, and folded while being heated moderately. The surface of the sealing member 10 on which the EVA film is coated becomes the bonding surface. The sealing member 10 has the horizontal bonding surface 11 facing the front side glass substrate 2 and the horizontal bonding surface 11 facing the rear side glass substrate 3, and each bonding surface is formed by folding a sealing sheet constituting the sealing member 10. Since the surface of the sealing member facing the outside air is not bonded, the stress in each horizontal bonding surface 11 will not interact with each other. Because of this, when the front side glass substrate 2, the intermediate film layer 4, and the rear side glass substrate 3 each expand and contract in the sealing process, the stress in the edges of the glass substrates will not be concentrated, so that breakage of the glass substrates can be suppressed even when the thickness of the intermediate film layer 4 is thin. Furthermore, forming an aluminum coating on the opposite surface to the bonding surface can improve a gas barrier property. In addition, instead of an aluminum coating, forming a silicon nitride coating, a silicon oxide coating, or a SiON coating may improve a gas barrier property. A deposition or a coating between films laminated with a film such as PET, etc. are suitable for forming these inorganic barrier films. Since fine cracks are generated in the folding process, an inorganic barrier layer may be formed on the surfaces of the sealing members 5 and 6 after the folding process. Forming the layer after the folding process can realize a sealing member which has no crack and an excellent gas barrier property. When assuming the moisture permeability of the EVA to be 10 g/m²·day (at 40° C. and 90% relative humidity based on JIS K7129), the moisture permeability of a sealing sheet is preferably less than the value. As described above, using an aluminum coating or various coatings based on the inorganic materials, this target value can be easily achieved. From a viewpoint of the gas barrier property, a film including an inorganic barrier coating made from a fluoride-based material described above is best suited. The area of the horizontal bonding surfaces 7 or 11 can be set suitably without depending on the thickness of the glass substrate. In addition, owing to the bonding interface up to the vertical bonding surfaces 8 or 13, the bonding through a long path from inside the module to the outside air can be made, and thus, a secure sealing can be realized. FIG. 3 shows an arrangement in the case where four pieces of the sealing members 10 shown in FIG. 2 are used and arranged correspondingly to four sides of a rectangular module. It is configured such that a pair of sealing members 10A for the short sides and a pair of sealing members 10B for the long sides are arranged so as to surround the outer edges of the rectangular module.

Since as the rear side glass substrate 3, a different material and a different thickness, and a different dimension from those of the front side glass substrate 2 can be allowed, when used as a solar cell module integrated with a building material, a configuration having higher structural strength than the front side glass substrate 2 is to be employed. For example, increasing the thickness of the substrate compared to the front side glass substrate 2 or using glass having higher strength can be possible. Furthermore, in the case where there is no reflecting layer on the backside of the solar cell 1, coating may be applied on the rear side glass substrate 3 as a light reflecting layer. In the case where the transparency of the rear side glass substrate 3 does not contribute to photovoltaic power, it goes without saying that coloring or attaching a film, etc. for adding functions as a building material may be possible as necessary. Employing two substrates made of glass and the sealing members 5 and 6, or 10 composed of the folded sealing sheets, a solar cell module having an excellent gas barrier property can be realized. Otherwise moisture entering the inside may corrode a metallic wire or a connection part, and also causes a degradation of thin film type solar cells and transparent conductive thin film layers. Therefore, an effect for improving the reliability of the module can be obtained. In addition, the configuration contributes to a characteristic stabilization when using a CIGS type solar cell which is particularly sensitive to moisture.

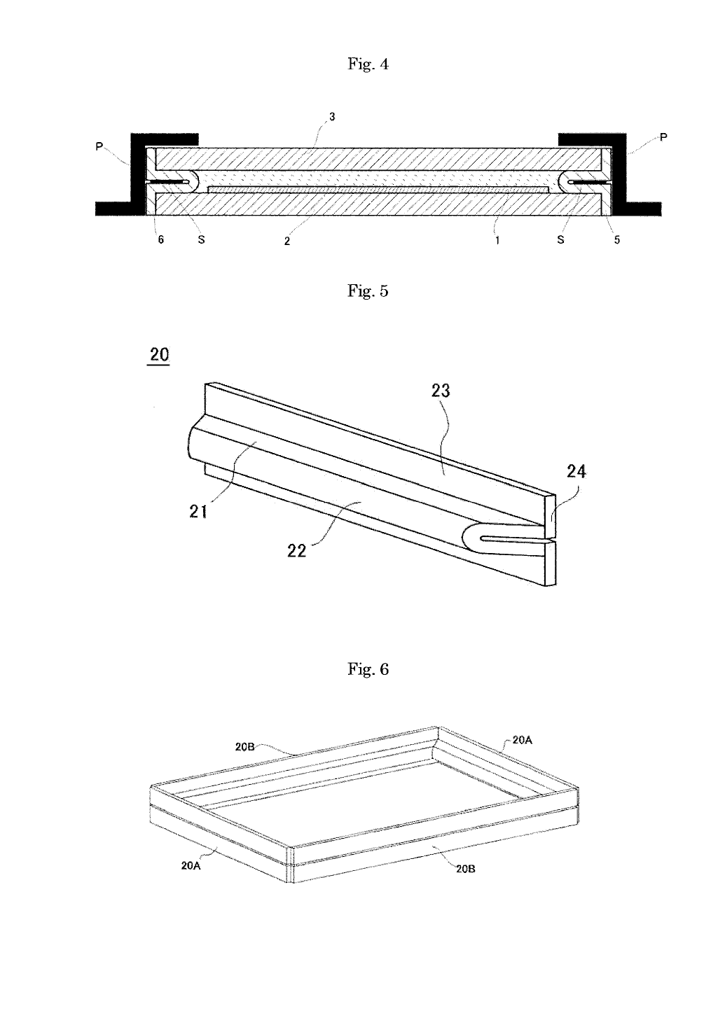

Next, a manufacturing method of a solar cell module 100 will be described. First, the sealing members 5 and 6, which are formed in advance by folding sealing sheets, are placed on edge sealing areas which are located in the periphery of the solar cell 1 on the front side glass substrate 2 (regarding the arrangement, refer to FIG. 3). On the structure described above, an intermediate film sheet and the rear side glass substrate 3 whose sizes are similar to the front side glass are placed overlappingly on the solar cell 1. FIG. 4 is a cross sectional view showing a situation where a solar cell module 100 is formed in the sealing process, and jigs P having a cross section as shown in FIG. 4 are attached so as to prevent the sealing sheet from coming off. There is a stage not shown in the figure under the front side glass substrate 2, and the bottom surface of the jigs P are fixed so as to maintain the positional relationship with respect to the stage. Preferably, the jigs P have heat resistance, and are composed of a material such as a fluorocarbon resin which has heat resistance, chemical resistance, and an anti-adherence property so as not to be bonded to the solar cell module with the intermediate film layer which overflows from between the glass substrates when pressurized. In the sealing process, a diaphragm is placed to entirely cover the jigs P and the solar cell module 100, and the entire module is pressurized from the outside and the inside of the solar cell module 100 is decompressed. In such a situation, the intermediate film sheet is melted by heating up the stage in a vacuum laminating machine, and covers the solar cell 1, and bonds the front side glass substrate 2 and the rear side glass substrate 3, resulting in the formation of the intermediate film layer 4. The intermediate film layer which is melted and extruded to the peripheral edges of the glass substrates in the vacuum laminating sealing process contributes to the bonding with the sealing members 5 and 6, and the upper and lower glass substrates. In addition, a surplus intermediate film layer may overflow from joints between the sealing members 5 and 6. By intentionally making gaps in the joints to use them as outlets for the intermediate film layer, the intermediate film layer which has overflowed and been solidified outside between the glass substrates can be cut by a cutter, etc., accordingly. The outlet described above can also be used as a passage for releasing a gas between the glass substrates. Further, spacers S in strip form are inserted inside the gaps G of the sealing members 5 and 6 before sealing, and removed after the sealing is completed, so that the thickness of the intermediate film layer 4 can be precisely controlled. A material for the spacers S may be selected accordingly from a thin stainless plate, aluminum foil, a heat-resistant polyimide film and the like.

Incidentally, in order to improve a gas barrier property of the module, a butyl rubber or a silicone resin may be applied in gaps generated in the contact areas of the neighboring sealing members 10A and 10B, so that a structure which prevents vapor from passing through the gaps of the sealing members can be realized. In addition, as the material used for the intermediate film layer 4, other than the EVA, a resin having a low moisture permeability and an adhesive property may be possible and not limited to the EVA. The height of the exterior part along the end face of the front side glass substrate 2 under the solar cell 1 may be smaller than the thickness of the glass substrate. Therefore, it can be avoided that the sealing member intercepts the sunlight incident on the front side glass substrate 2.

Next, a specific configuration where the solar cell module 100 is a thin film type solar cell module will be described. FIG. 9 is a plan view showing a configuration of a thin film type solar cell module 200. A plurality of thin film solar cells 201 disposed in parallel on a front side glass substrate 202 are serially connected so as to configure an integrated solar cell device. On one side and the other side thereof, a positive electrode collector and a negative electrode collector are formed respectively. In general, each thin film solar cell 201 has an elongated rectangular shape and long sides of the rectangle have a length extending almost over the whole width of the front side glass substrate 202. The neighboring thin film solar cells are connected in series in which a transparent electrode film of one cell and a rear electrode film of the other cell are connected. A linear p-type electrode terminal 210, which has almost the same length with the thin film solar cell, is formed on an edge of the transparent electrode film of an endmost thin film solar cell connected in series. Further, a similar n-type electrode terminal 220 is formed on an edge of the rear electrode film of a thin film solar cell at the other end. Those p-type electrode terminal 210 and n-type electrode terminal 220 become electrode extraction portions. A positive electrode collector made of copper foil called a bus bar having the same shape with the p-type electrode terminal is connected electrically and mechanically in the whole surface of the p-type electrode terminal 210. In the same way, a negative electrode collector having the same shape with the n-type electrode terminal 220 are connected in the whole surface of the p-type electrode terminal 220. Further, a positive electrode lead wire and a negative electrode lead wire are respectively connected to the positive electrode collector and the negative electrode collector. The other ends of the positive lead wire and the cathode lead wire are pulled out through the rear side glass substrate in one case, and in another case, they are pulled out from the peripheral edges of the glass substrate. In order to protect the peripheral edges of the module, the module is configured with an aluminum frame which fits around the periphery of the glass substrates. Meanwhile, a frameless solar cell module 100 without a frame may be employed. In this case, although the frame weight and the cost can be reduced, a problem arises that the module can be easily damaged when the edges of the glass substrates are exposed. In the solar cell module 100 described above, the edges of the glass substrates are covered with the sealing members 5 and 6, so that the edges of the glass substrates, which are easily damaged by shock, are not exposed, but protected with the sealing sheets. Moreover, since the folded insertion parts of the sealing member 5 and 6 are inserted between the glass substrates, the bonding strength between the sealing members 5, 6 and the glass substrates are high, and they hardly peel off. Incidentally, in an example of the arrangement for the sealing members 10A and 10B as shown in FIG. 3, portions from which the glass substrates are exposed are to be created in the outer sides of both the ends of the sealing member 10A. Therefore, an embodiment in which the shape of the sealing member 10A is modified to extend the portions corresponding to the vertical bonding surfaces 8 or 13, may be adopted. Using the structure like this, a frameless module can be easily realized without preparing additional members for protecting the edges. Incidentally, the solar cell 1 is not limited to the thin film solar cell. Also in a type of a solar cell module where solar cells manufactured based on a crystalline semiconductor substrate are attached on the front side glass substrate 2, the edge sealing of the module can be realized by carrying out a similar process in the sealing area around the solar cell area.

### Embodiment 2

A solar cell module according to Embodiment 2 is a module similar to Embodiment 1 having a structure using laminated glass, and compared to Embodiment 1, the shape of the sealing member is different. FIG. 5 is a perspective view showing a configuration of a sealing member 20 which is used for sealing edges of a solar cell module having a structure using laminated glass according to Embodiment 2. It is configured such that both ends of a horizontal bonding surface 21, which become joints when the module is constructed, are cut so as to make 45 degrees with respect to the vertical bonding surface 23. An easy formation of four sides of the rectangle by joining the four members together is intended. FIG. 6 illustrates an arrangement of the sealing members when the sealing members 20A and 20B having this shape are arranged, and thus the formation where four sides of the module are surrounded without gaps can be realized. Similar to Embodiment 1, using sealing members having a folded shape, breakage of glass in the sealing process can be suppressed. In addition, a butyl rubber or a silicone resin may be applied on the 45-degree cut surfaces of the sealing members 20A and 20B or the joints, so that a sealing structure having a high gas barrier property can be obtained.

### Embodiment 3

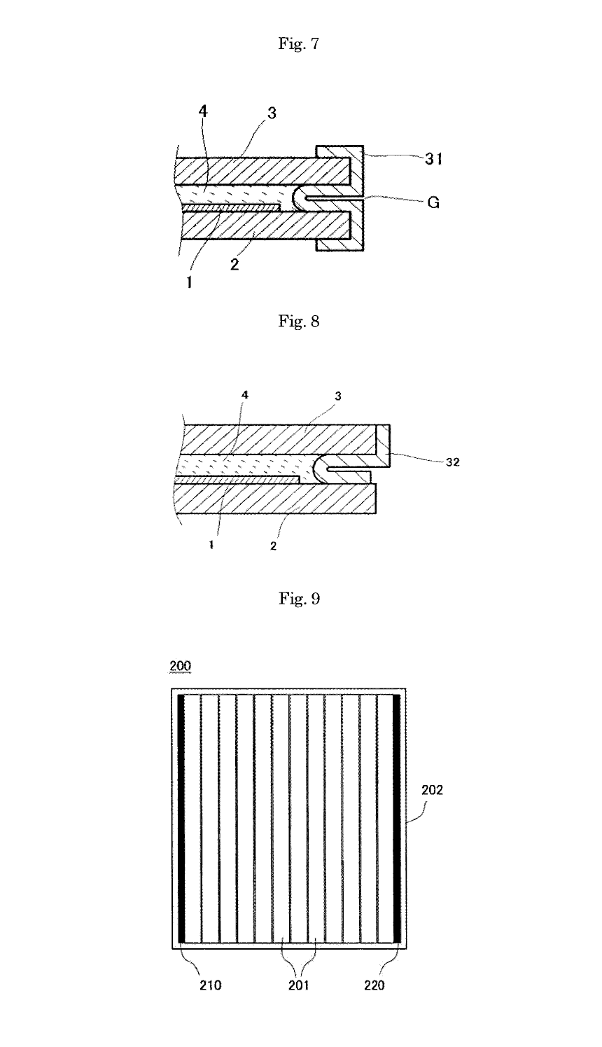

A solar cell module according to Embodiment 3 is a module similar to Embodiment 1 having a structure using laminated glass, and compared to Embodiment 1 and Embodiment 2, the shape of the sealing member is different. FIG. 7 is an enlarged cross-sectional view regarding a cross section of the right-side edge of a solar cell module having a structure using laminated glass according to Embodiment 3 of the invention. The sealing member 31 of FIG. 7 has a structure in which the exterior parts covering the edges of the front side glass substrate 2 and the rear side glass substrate 3 are extended from the vertical bonding surfaces and folded onto the primary surfaces being exterior surfaces of the module. With this method, the protection of the edges of the glass substrates from damage can be enhanced, and workability during construction of the module can be improved. In addition, peeling of the sealing member 31 at the edges of the glass substrates can be suppressed. Similar to the embodiments described above, using a sealing member with a folded shape, breakage of glass in the sealing process can be suppressed. Incidentally, the width along which the sealing member 31 covers the periphery of the front side glass substrate 2 is determined in such a way that the light reception area will not be reduced by the sealing member 31 interrupting incident light. For example, when using a thin film type solar cell, the sealing member should be placed not to cover the inside from the edge deletion area at the periphery of the substrate.

### Embodiment 4

A solar cell module according to Embodiment 4 is a module similar to Embodiment 1 having a structure using laminated glass, and compared to Embodiment 2 described above, the shape of the sealing member is different. FIG. 8 is an enlarged cross-sectional view of the right side of the solar cell module having a structure using laminated glass according to Embodiment 4. In a sealing member 32 of FIG. 8, the exterior part covers the end face of the rear side glass substrate 3, but does not cover the end face of the front side glass substrate 2. In the sealing process as mentioned above, the intermediate film layer 4 which is melted and extruded toward the edges of the glass substrates will intrude into the interfaces between the sealing member and the upper and lower glass substrates. In this situation, when the intermediate film layer 4 is excessive in amount, the intermediate film layer 4 will protrude from between the sealing member 32 and the glass substrates. Using the sealing member 32, even when the protrusion toward the front side glass substrate 2 occurs, the intermediate film layer 4 can be prevented from wrapping around the prime surface of the front side glass substrate 2 on the light receiving side. In addition, similar to the embodiments described above, using a sealing member having a folded shape, breakage of glass in the sealing process can be suppressed. Furthermore, in the case where the lead wires are placed along the front side glass substrate 2 and pulled out from the edges of the front side glass substrate 2, the lead wires do not need to go through the sealing member 32. In the sealing process, by removing portions of the spacers S corresponding to the locations of the lead wires, the sealing member 32 can be deformed along the lead wires. Therefore, in the type in which lead wires are pulled out from the periphery of the front side glass substrate 2, productivity of the sealing process of the solar cell module 100 can be enhanced by using the sealing member 32.

### EXPLANATION OF REFERENCE CHARACTERS

1: Solar cell
2: Front side glass substrate
3: Rear side glass substrate
4: Intermediate film layer
5, 6, 10, 20, 31, 32: Sealing members
S: Spacer

1-7. (canceled)

8. A solar cell module, comprising:
a laminated glass structure in which a solar cell and a translucent intermediate film layer which seals the solar cell are interposed between a first glass substrate in a light receiving surface side and a second glass substrate in a rear surface side; and
a sealing member in a peripheral edge of the first glass substrate in which an insertion part and at least one exterior part are formed by folding a sealing sheet having a bonding surface on one side, wherein
the insertion part is formed by folding back the sealing sheet,
the at least one exterior part is formed to be connected continuously to the insertion part,
the insertion part is inserted between the first glass substrate and the second glass substrate, and the bonding surface thereof is bonded to the first glass substrate and the second glass substrate, and
the bonding surface of the at least one exterior part is bonded to an end face of the first glass substrate or the second glass substrate.

9. The solar cell module according to claim 8, wherein the sealing member includes a pair of exterior parts, one of the exterior parts is bonded to the end face of the first glass substrate, and the other exterior part is bonded to the end face of the second glass substrate.

10. The solar cell module according to claim 9, wherein the principal component of the translucent intermediate film layer is an ethylene-vinyl acetate copolymer, and a layer of an ethylene-vinyl acetate copolymer is formed on the bonding surface of the sealing member.

11. The solar cell module according to claim 9, wherein the sealing sheet is a film using a resin film as a base material, and any one of a silicon nitride film, a silicon oxide film, and a SiON film is formed on a surface opposite to the bonding surface of the resin film.

12. The solar cell module according to claim 8, wherein the principal component of the translucent intermediate film layer is an ethylene-vinyl acetate copolymer, and a layer of an ethylene-vinyl acetate copolymer is formed on the bonding surface of the sealing member.

13. The solar cell module according to claim 8, wherein the sealing sheet is a film using a resin film as a base material, and any one of a silicon nitride film, a silicon oxide film, and a SiON film is formed on a surface opposite to the bonding surface of the resin film.

14. A manufacturing method for a solar cell module according to claim 8, the method comprising:
disposing an intermediate film sheet, which is to be the translucent intermediate film layer, on a solar cell on the first glass substrate;
disposing the sealing member so as to surround the peripheral part of the first glass substrate;
disposing the second glass substrate on the intermediate film sheet; and
heating and softening the intermediate film sheet.

15. The manufacturing method for a solar cell module according to claim 14, wherein the insertion part and the at least one exterior part of the sealing member are formed by heating the sealing sheet in advance, and sealing is carried out while disposing the sealing member in the peripheral part of the first glass substrate or the second glass substrate.

16. The manufacturing method for a solar cell module according to claim 15, wherein the sealing is carried out while inserting a spacer between a surface of the sealing member opposite to the bonding surface for the first glass substrate and a surface opposite to the bonding surface for the second glass substrate.
